(19) United States
(12) Patent Application Publication
(10) Pub. No.: US 2014/0203291 A1
(43) Pub. Date: Jul. 24, 2014

(54) SEMICONDUCTOR DEVICE AND METHOD FOR FABRICATING THE SAME

(71) Applicant: FUJITSU SEMICONDUCTOR LIMITED, Yokohama (JP)

(72) Inventor: Koichi Nakamura, Fuchu (JP)

(73) Assignee: FUJITSU SEMICONDUCTOR LIMITED, Yokohama (JP)

(21) Appl. No.: 14/096,344

(22) Filed: Dec. 4, 2013

(30) Foreign Application Priority Data
Jan. 24, 2013 (JP) 2013-011458

(51) Int. Cl. H01L 23/00

(52) U.S. Cl. CPC H01L 24/14; H01L 24/11
USPC 257/76; 257/737; 438/613

(57) ABSTRACT

A semiconductor device includes: an FET chip; pads provided on an upper surface of the FET chip; bumps provided on at least one of the pads; leads having first portions that are connected to the FET chip by the bumps and extend along the upper surface of the FET chip, and second portions that contact surfaces of the first portions along the upper surface of the FET chip and extend along a side surface of the FET chip, the first and second portions being formed by press or cutting; and a seal layer that seals the FET chip and the leads and a surface from which the second portions of the leads are exposed, the surface of the seal layer being on a lower surface side of the FET chip.

### CROSS-REFERENCE TO RELATED APPLICATIONS

This application is based upon and claims the benefit of priority of the prior Japanese Patent Application No. 2013-011458, filed on Jan. 24, 2013, the entire contents of which are incorporated herein by reference.

### FIELD

A certain aspect of the embodiments discussed herein is related to a semiconductor device, a method for fabricating the same, a lead and a method for producing the lead.

### BACKGROUND

Recently, flip-chip connections have been largely made in which a semiconductor chip is flip-chip connected to a lead by bumps. For example, it is known that a semiconductor chip is flip-chip connected to a bent lead (see Japanese Laid-Open Patent Publication No. 11-340373). It is also known to use leads having various shapes to which semiconductor chips are flip-chip connected (see Japanese Laid-Open Patent Publication Nos. 7-130918, 2003-258187, 2005-252018 and 2005-311099).

An FET (Field Effect Transistor) chip has pads on its upper surface for making connections to the source, drain and gate. The flip-chip connection of the FET chip to the lead may have only a short distance between the adjacent terminals and a semiconductor device with the FET may fail. It is conceivable to use a lead subjected to a bending process in order to increase the terminal-to-terminal distance. However, there is a possibility that the lead does not withstand a large amount of current and the reliability of the semiconductor device is degraded.

When the FET chip is flip-chip connected to the lead, a connection failure such as a void in making a connection may occur, and the reliability of the semiconductor device is thus degraded.

### SUMMARY

According to an aspect of the present invention, there is provided a semiconductor device including: an FET chip; pads provided on an upper surface of the FET chip; bumps provided on at least one of the pads; leads that include first portions that are connected to the FET chip by the bumps and extend along the upper surface of the FET chip, and second portions that contact surfaces of the first portions along the upper surface of the FET chip and extend along a side surface of the FET chip, the leads being formed by press or cutting; and a seal layer that seals the FET chip and the leads and a surface from which the second portions of the leads are exposed, the surface of the seal layer being on a lower surface side of the FET chip.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A through 1D are cross-sectional views of semiconductor devices in accordance with first through fourth comparative examples, respectively;

FIG. 2 is a plan view of a semiconductor device seen through the upper surface thereof in accordance with a fifth comparative example;

FIG. 3A is a plan view of a semiconductor device seen through the upper surface thereof in accordance with a first embodiment, and FIG. 3B is a cross-sectional view taken along a line A-A in FIG. 3A;

FIG. 4A is a top view of an FET chip, and FIG. 4B is an enlarged top view of a part of an area surrounded by a dotted line;

FIGS. 5A and 5B are cross-sectional views that illustrate a method for producing a leadframe, and FIGS. 5C and 5D are top views that illustrate the method for producing the leadframe;

FIG. 6 is a top view that illustrates the method for producing the lead frame following the steps of FIGS. 5A through 5D;

FIGS. 7A through 7D are cross-sectional views that illustrate a method for fabricating a semiconductor device;

FIG. 8 is a cross-sectional view of a semiconductor device in accordance with a sixth comparative example;

FIG. 9A is a plan view of a semiconductor device seen through the upper surface thereof in accordance with a first variation of the first embodiment, and FIG. 9B is a cross-sectional view taken along a line A-A in FIG. 9A;

FIG. 10A is a top view of a semiconductor device in accordance with a second embodiment, FIG. 10B is a bottom view of the semiconductor device, and FIG. 10C is a cross-sectional view taken along a line A-A in FIG. 10B;

FIG. 11 is a cross-sectional view that illustrates a method for producing a leadframe;

FIG. 12A through 12D are cross-sectional views that illustrate a method for fabricating a semiconductor device;

FIG. 13 is a cross-sectional view of a device composed of two stacked semiconductor devices of the second embodiment;

FIG. 14A is a top view of a semiconductor device in accordance with a first variation of the second embodiment, FIG. 14B is a bottom view of the semiconductor device, and FIG. 14C is a cross-sectional view taken along a line A-A in FIG. 14A;

FIG. 15 is a cross-sectional view of a device composed of two stacked semiconductor devices of the first variation of the second embodiment; and

FIG. 16A is a top view of a semiconductor device in accordance with a second variation of the second embodiment, and FIG. 16B is a cross-sectional view taken along a line A-A in FIG. 16A.

### DESCRIPTION OF EMBODIMENTS

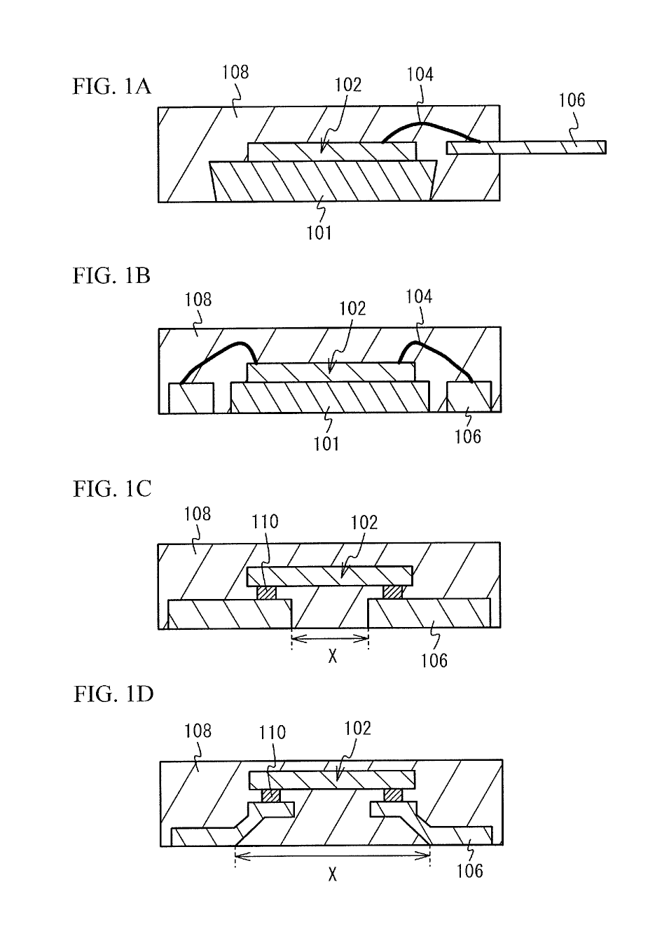

Now, some comparative examples are described. FIG. 1A is a cross-sectional view of a semiconductor device in accordance with a first comparative example. FIG. 1B is a cross-sectional view of a semiconductor device in accordance with a second comparative example. As illustrated in FIGS. 1A and 1B, an FET chip 102 mounted on a heat radiating plate 101 made of a metal is electrically connected to a lead 106 by a wire 104. The FET chip 102 and the wire 104 are sealed with a seal layer 108.

The connection of the FET chip 102 to the lead 106 made by wire bonding affects the high-speed operation of the FET chip 102 because of a large inductance of the wire 104. This adverse effect is conspicuous if the FET chip 102 is a high-speed-operation device such as HEMT (High Electron Mobility Transistor). It is therefore conceivable to make a flip-chip connection of the FET chip 102 to the lead 106 without any wire.

FIG. 1C is a cross-sectional view of a semiconductor device in accordance with a third comparative example. As illustrated in FIG. 1C, the FET chip 102 is flip-chip connected to the lead 106 by bumps 110. The third comparative example does not use any wire but makes connections to the lead 106 by the bumps 110, so that the inductance can be suppressed. The FET chip 102 is structured to have a source pad, a drain pad, and a gate pad electrically connected to the source electrode, the drain electrode and the gate electrode respectively on an identical surface (the upper surface, for example). This structure adversely results in a short distance X between the terminals of the lead 106 connected to the source pad and the drain pad. For example, the terminal-to-terminal distance X is as short as 1 to 2 mm. The short distance X may cause the FET chip 102 to fail. The FET chip 102 is likely to fail when the FET chip 102 is a device that operates at high voltages such as a HEMT chip using a GaN-based semiconductor. The GaN-based semiconductor is a semiconductor including GaN.

FIG. 1D is a cross-sectional view of a semiconductor device in accordance with a fourth comparative example. As illustrated in FIG. 1D, the lead 106 has been subjected to a bending process and has a large terminal-to-terminal distance X. However, the lead 106 has a reduced cross section, which increases the current density. As a result, the lead 106 does not withstand a large amount of current and degrades the reliability of the semiconductor device.

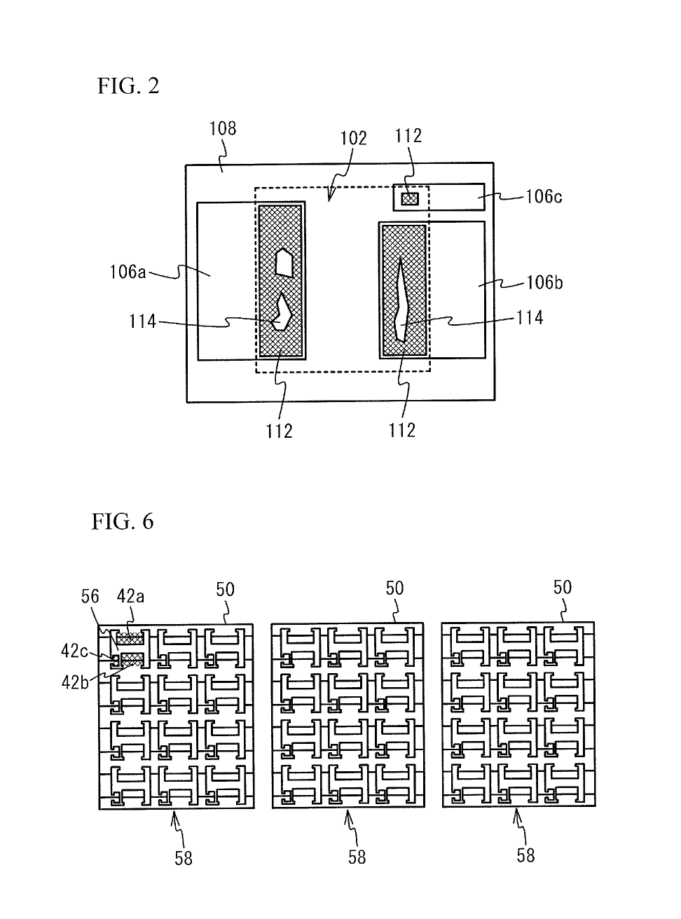

Since the FET chip 102 has a large area occupied by the source pad, the drain pad and the gate pad, a bonding failure may take place in making the flip-chip connection. FIG. 2 is a plan view of a semiconductor device seen through the upper surface of the semiconductor device in accordance with a fifth comparative example. When the whole source pad of the FET chip 102 is connected to a lead 106a for the source by a solder 112, a void 114 may occur at the interface because the source pad has a large area. Similarly, when the whole drain pad of the FET chip 102 is connected to a lead 106b for the drain by a solder 112, a void 114 may occur at the interface because the drain pad has a large area. If the gate pad of the FET chip 102 has a small area, it is possible to suppress the occurrence of a void at the interface with a lead 106c for the gate. As described above, a connection failure such as a void at the interfaces between the pads of the FET chip 102 and the leads degrades the reliability of the semiconductor device.

A description is now given of embodiments directed to improving the reliability of the semiconductor device.

### First Embodiment

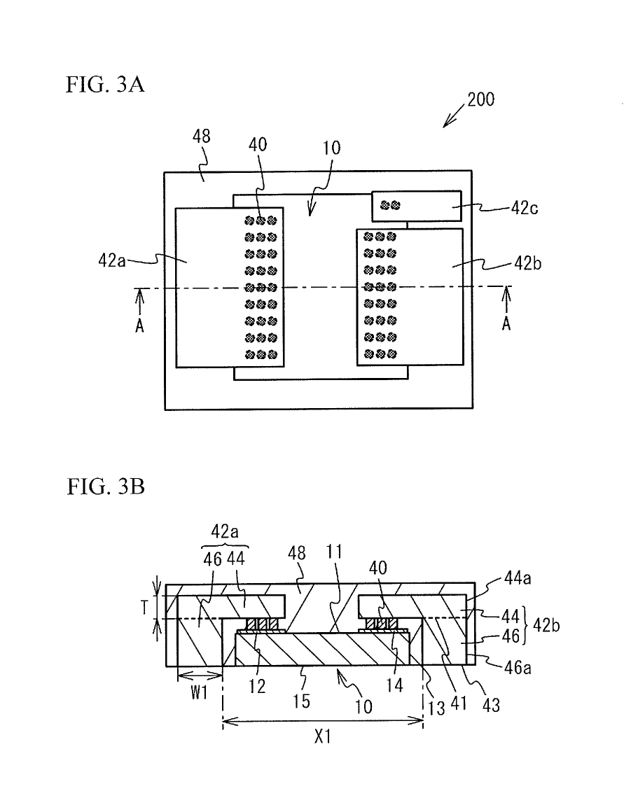

FIG. 3A is a plan view of a semiconductor device seen through an upper surface thereof in accordance with a first embodiment, and FIG. 3B is a cross-sectional view taken along a line A-A in FIG. 3A. As illustrated in FIGS. 3A and 3B, a semiconductor device 200 of the first embodiment has the FET chip 10, which is flip-chip connected to leads 42a˜42c by bumps 40. The FET chip 10 is, for example, a HEMT chip using a GaN-based semiconductor. The bumps 40 are solder bumps, for example. The leads 42a˜42c are formed of a metal such as copper.

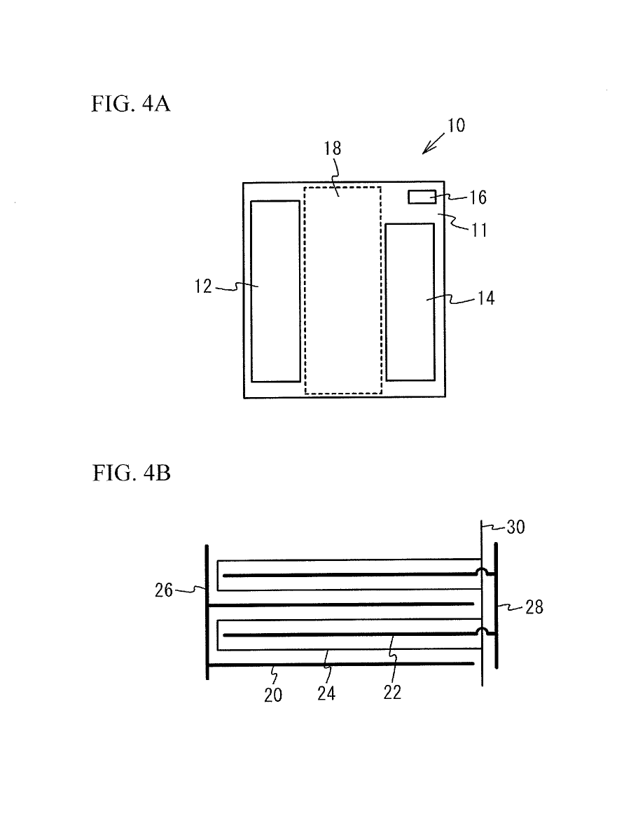

A further description is now given of the FET chip 10. FIG. 4A is a top view of the FET chip 10, and FIG. 4B is an enlarged top view of a part of an area 18 surrounded by a dotted line. Referring to FIGS. 4A and 4B, the FET chip 10 has a source pad 12, a drain pad 14, and a gate pad 16 on an upper surface 11. The area 18 that is surrounded by the dotted line and is interposed between the source pad 12 and the drain pad 14 is a transistor portion of the FET chip 10. The transistor portion of the FET chip 10 includes an aggregate of comb-tooth structures, each of which has an arrangement in which the gate electrode 24 is interposed between the source electrode 20 and the drain electrode 22. A source interconnection line 26 to which a plurality of source electrodes 20 are connected is electrically connected to the source pad 12. Similarly, a drain interconnection line 28 to which a plurality of drain electrodes 22 are connected is electrically connected to the drain pad 14. A gate interconnection line 30 to which a plurality of gate electrodes 24 are connected is electrically connected to the gate pad 16. As described above, the FET chip 10 has one transistor portion, and the pads on the upper surface 11 of the FET chip 10 are electrically connected to the transistor portion. Portions in which the gate interconnection line 30 crosses the drain electrodes 22 have a three-dimensional structure in which an insulator (not illustrated) is provided between the gate interconnection line 30 and the drain electrodes 22, which are electrically isolated from each other.

As illustrated in FIGS. 3A and 3B, the source pad 12 on the upper surface 11 of the FET chip 10 is connected to a lead 42a by a plurality of bumps 40. The drain pad 14 on the upper surface 11 of the FET chip 10 is connected to a lead 42b by a plurality of bumps 40, and the gate pad 16 on the upper surface 11 is connected to a lead 42c by a plurality of bumps 40. The plurality of bumps 40 are provided to each of the source pad 12, the drain pad 14 and the gate pad 16 on the upper surface 11 of the FET chip 10. The plurality of bumps 40 are regularly arranged in rows and columns at constant intervals, for example.

Each of the leads 42a˜42c has a first portion 44 and a second portion 46. The first portion 44 extends along the upper surface 11 of the FET chip 10. The second portion 46 contacts a surface 41 of the first portion 44 along the upper surface 11 of the FET chip 10 and extends along a side surface 13 of the FET chip 10. That is, each of the leads 42a˜42c has an L-shaped cross section. The bumps 40 are connected to the first portions 44. A side surface 44a of the first portion 44 and a side surface 46a of the second portion 46 form a single surface. The first portion 44 and the second portion 46 are cuboids, for example. Thus, the corners of the leads 42a˜42c have right angles. For example, the thickness T of the first portion 44 is 0.25 mm, and the width W1 of the second portion 46 is 0.5 mm. As described above, the thickness T of the first portion 44 and the width W1 of the second portion 46 have mutually different values, and the width W1 is larger than the thickness T. The FET chip 10 is arranged between the lead 42a and the lead 42b and between the lead 42a and the lead 42c so as to be surrounded or sandwiched by the leads 42a˜42c.

The FET chip 10 and the leads 42a˜42c are sealed with a seal layer 48. For example, the seal layer 48 is made of resin such as epoxy resin. A lower surface 15 of the FET chip 10 is exposed from the seal layer 48 in order to improve the heat radiation performance. The second portions 46 of the leads 42a˜42c are exposed from the seal layer 48 on the lower surface 15 side of the FET chip 10 in order to have the second portions 46 function as terminals for making electric connections between the FET chip 10 and an external circuit. The lower surface 15 of the FET chip 10 is flush with a surface 43 of the second portion 46 exposed from the seal layer 48. The second portion 46 of the lead 42a electrically connected to the source pad 12 of the FET chip 10 and the second portion 46 of the lead 42b electrically connected to the drain pad 14 are exposed from the seal layer 48 in positions at opposite sides of the FET chip 10. A terminal-to-terminal distance X1 between the lead 42a and the lead 42b is 6 mm, for example.

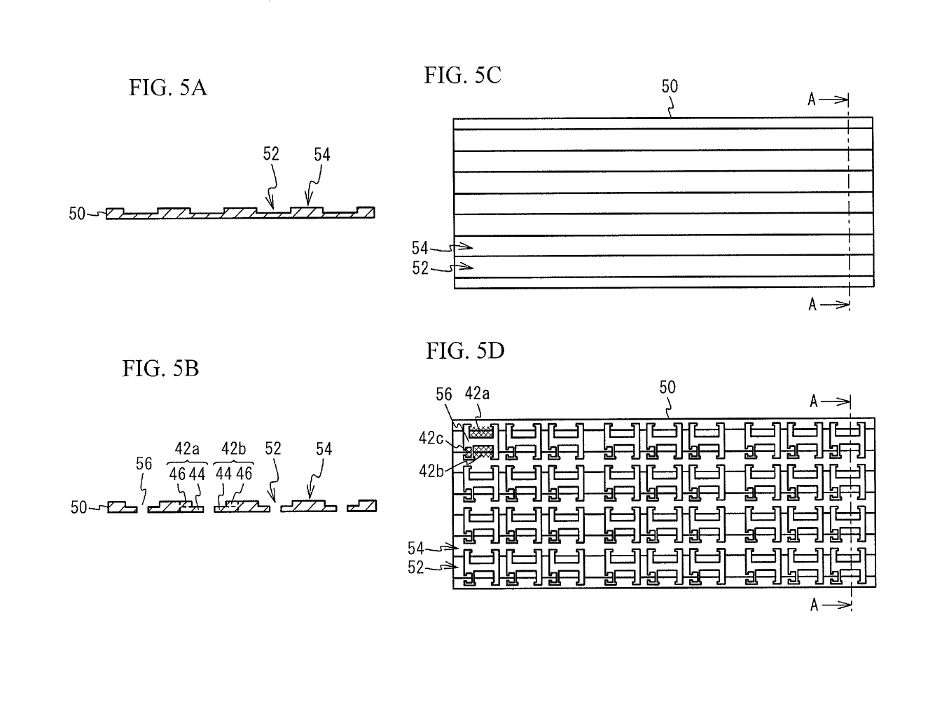

A description is now given of a method for fabricating the semiconductor device in accordance with the first embodiment with reference to FIGS. 5A through 5D, 6 and 7A through 7D. First, a method for producing a leadframe with reference FIGS. 5A through 5D and 6. FIGS. 5A and 5B are cross-sectional views that illustrate a method for producing a leadframe, and FIGS. 5C, 5D and 6 are top views that illustrate the method for producing the lead frame. FIG. 5A is a cross-sectional view taken along a line A-A in FIG. 5C, and FIG. 5B is a cross-sectional view taken along a line A-A in FIG. 5D.

As illustrated in FIGS. 5A and 5C, a metal plate 50 such as a copper plate is prepared. The metal plate 50 has groove portions 52 and bank portions 54 that are stripe-shaped portions and are arranged in turn repeatedly. The metal plate 50 may be obtained by press or cutting a plate metal plate. For example, the metal plate 50 has a thickness of 0.25 mm in the groove portions 52, and a thickness of 0.5 mm in the bank portions 54. Then, the metal plate 50 is plated with a metal. The plating may be carried out for the whole surfaces of the metal plate 50 or only limited portions, which may be the stripe-shaped bank portions 54.

As illustrated in FIGS. 5B and 5D, the metal plate 50 is processed by press with a mold to define the leads 42a˜42c and form a plurality of cutout patterns 56 in which the metal plate 50 is removed. More specifically, the pressing work uses a mold having patterns formed by removing shapes of the first portions 44 of the leads 42a˜42c (see FIGS. 3A and 3B) from a rectangle. For example, the cutout patterns 56 are formed so as to be arranged in rows and columns in the metal plate 50. The mold is pressed so that portions removed from the rectangle (that is, portions corresponding to the leads 42a˜42c) connect the groove portions 52 and the bank portions 54 together. The cutout patterns 56 define the leads 42a˜42c that extend from the groove portions 52 to the bank portions 54. The leads 42a˜42c defined by the cutout patterns 56 include the flat first portions 44 and the second portions 46 due to the steps formed by the groove portions 52 and the bank portions 54. The second portions 46 contact the first portions 44 and extend in the direction in which the second portions 46 cross the first portions 44. The cutout patterns 56 may be formed by cutting instead of press.

As illustrated in FIG. 6, the metal plate 50 is cut in predetermined positions. This cutting divides the metal plate 50 into a plurality of regions, each of which includes a plurality of leads 42a˜42c. Each region is a leadframe 58. Each of the leadframes 58 has a plurality of regions on which FET chips 10 are mountable.

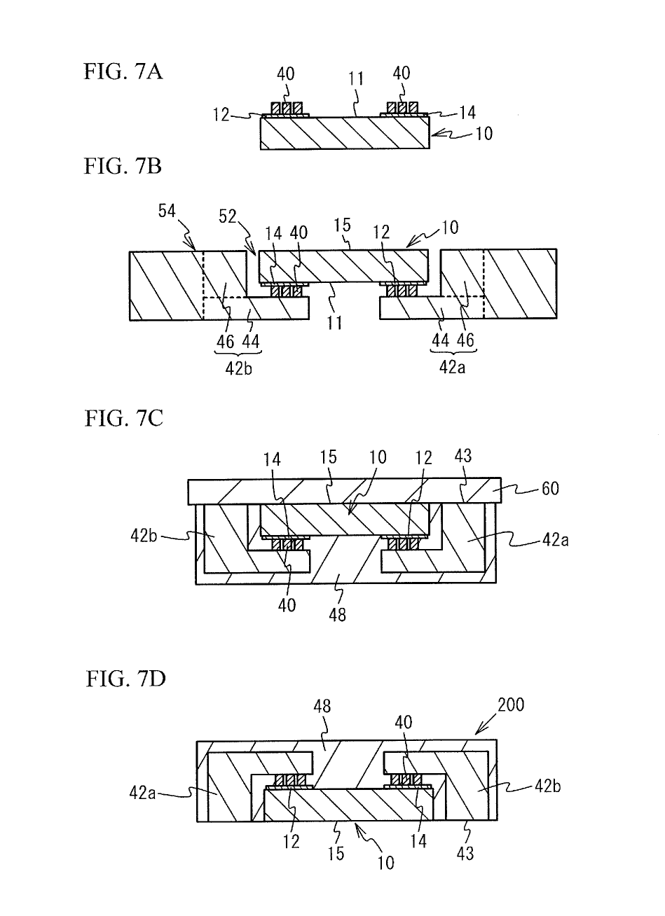

A description is given, with reference to FIGS. 7A through 7D, of a method for fabricating a semiconductor device using the leadframes 58 produced by the method illustrated in FIGS. 5A through 5D and 6. FIGS. 7A through 7D are cross-sectional views that illustrate a method for fabricating a semiconductor device. It is to be noted that FIGS. 7A through 7D depict only one semiconductor device for the sake of simplicity. Referring to FIG. 7A, a plurality of bumps 40 are formed on each of the source pad 12, the drain pad 14 and the gate pad 16 (not illustrated) on the upper surface of the FET chip 10. The bumps 40 are solder bumps, for example.

Referring to FIG. 7B, the bumps 40 on the pads on the upper surface 11 of the FET chip 10 are connected to the leads 42a˜42c (lead 42c is not illustrated) defined by the respective cutout patterns 56. More specifically, the first portions 44 (that is, the groove portions 52) of the leads 42a˜42c are connected to the bumps 40. Thus, the FET chip 10 is arranged between the leads 42a and 42b and between the leads 42a and 42c so as to be surrounded by the leads 42a˜42c. It is preferable the heights of the groove portions 52 and the bank portions 54 are adjusted beforehand so that the lower surface 15 of the FET chip 10 is flush with the bank portions 54.

As illustrated in FIG. 7C, the metal plate 50 is divided into individual chips by cutting. Since the cutout patterns 56 are arranged in rows and columns, the individual chips are easily obtained from the plurality of FET chips 10 by cutting the metal plate 50. After cutting, a relief film 60 is attached to the lower surface 15 of the FET chip 10 and the surfaces 43 of the leads 42a˜42c on the lower surface 15 side of the FET chip 10, whereby the FET chip 10 and the leads 42a˜42c are molded. By this molding, the seal layer 48 that seals the FET chip 10 and the leads 42a˜42c is formed. The seal layer 48 is resin such as epoxy resin, for example.

As illustrated in FIG. 7D, the relief film 60 is removed. The lower surface 15 of the FET chip 10 and the surfaces of the leads 42a˜42c are exposed from the seal layer 48. FIG. 7D illustrates the packaged semiconductor device 200 of the first embodiment.

According to the first embodiment, as illustrated in FIG. 3B, each of the leads 42a˜42c has the first portion 44 that extends along the upper surface 11 of the FET chip 10, and the second portion 46 that contacts the surface 41 of the first portion 44 along the upper surface of the FET chip 10 and extends along the side surface 13 of the FET chip 10. The leads 42a˜42c are sealed with the seal layer 48, and the second portions 46 of the leads 42a˜42c are exposed from the seal layer 48 on the lower surface 15 side of the FET chip 10 in order to have the second portions 46 function as external terminals. With this structure, the second portion 46 of the lead 42a electrically connected to the source pad 12 and the second portion 46 of the lead 42b electrically connected to the drain pad 14 are exposed from the seal layer 48 in positions between which the FET chip 10 is interposed. It is thus possible to increase the terminal-to-terminal distance X1 between the leads 42a and 42b and to improve the reliability of the semiconductor device.

As illustrated in FIGS. 3A and 3B, the plurality of bumps 40 are provided to each of the source pad 12, the drain pad 14 and the gate pad 16 of the FET chip 10. The FET chip 10 is connected to the leads 42a˜42c by the plurality of bumps 40. This structure realizes the bumps 40 each having a small area and avoids the occurrence of voids that have been described with reference to FIG. 2. Further, the use of the plurality of bumps 40 relaxes stress applied to one bump 40. It is thus possible to suppress the occurrence of failure of bonding the FET chip 10 and the leads 42a˜42c and to improve the reliability of the semiconductor device.

As illustrated in FIGS. 5A and 5C, the fabrication method of the first embodiment uses the metal plate 50 having the groove portions 52 and the bank portions 54 in the form of stripes. As illustrated in FIGS. 5B and 5D, the cutout patterns 56 for defining the leads 42a˜42c extending from the groove portions 52 to the bank portions 54 are formed in the metal plate 50 by press or cutting. As illustrated in FIG. 7B, the bumps 40, which are provided on each of the source pad 12, the drain pad 14 and the gate pad 16 on the upper surface 11 of the FET chip 10, are connected to the groove portions 52 of the leads 42a˜42c defined by the cutout pattern 56. As illustrated in FIGS. 7C and 7D, the metal plate 50 is divided into the individual FET chips 10 by cutting, and the FET chip 10 and the leads 42a˜42c are sealed so that the surfaces 43 of the leads 42a˜42c on the lower surface 15 side of the FET chip 10 are exposed.

With the above steps, it is possible to easily fabricate the semiconductor device having the FET chip 10 connected through the bumps 40 to the leads 42a˜42c each having the first portion 44 extending along the upper surface 11 of the FET chip 10 and the second portion extending along the side surface 13. Further, according to the fabrication method described above, the leads 42a˜42c are formed by press or cutting. That is, the cutout patterns 56 for defining the leads 42a˜42c extending from the groove portions 52 to the bank portions 54 are formed in the metal plate 50 by press or cutting, and the metal plate 50 is cut. Through the above steps, the leads 42a˜42c are formed.

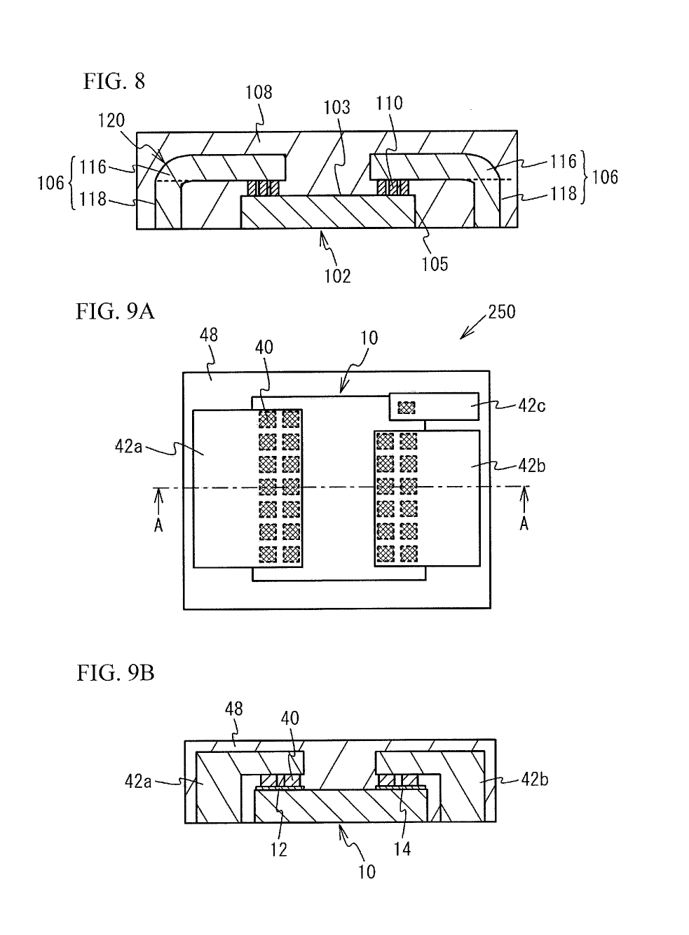

FIG. 8 is a cross-sectional view of a semiconductor device in accordance with a sixth comparative example. As illustrated in FIG. 8, if the lead 106 that extends along an upper surface 103 and a side surface 105 of an FET chip 102 is formed by bending, the use of a thick lead having a large cross section results in a large radius of curvature at a corner 120, and has a difficulty in downsizing of the semiconductor device. In contrast, the use of a thin lead for the purpose of reducing the radius of curvature at the corner 120 reduces the cross section and increases the current density. In the case where the lead 106 is formed by bending, the thickness of a first portion 116 along the upper surface 103 of the FET chip 102 is equal to the width of a second portion 118 along the side surface.

On the contrary, according to the first embodiment, the leads 42a˜42c are formed by press or cutting. It is therefore possible to obtain the leads 42a˜42c having a small radius of curvature at the corner and a large cross section. It is thus possible to realizing downsizing of the semiconductor device and reduce the current density and to thus improve the reliability of the semiconductor device. The use of press or cutting for forming the leads 42a˜42c makes it possible to arbitrarily select the thickness T of the first portion 44 and the width W1 of the second portion 46 and set T and W1 to different values. Thus, the degree of freedom of designing the leads 42a˜42c is improved.

The fabrication method of the first embodiment is capable of easily forming the leads 42a˜42c that are respectively connected to the source pad 12, the drain pad 14 and the gate pad 16 and are electrically isolated from each other.

It is preferable that the cutout patterns 56 are arranged in rows and columns in the metal plate 50. It is preferable that the FET chip 10 is connected, by the bumps 40, to the groove portions 52 of the leads 42a˜42c defined by the respective cutout patterns 56. Preferably, the metal plate 50 is cut into the individual FET chips 10 in the outer portions of the cutout patterns 56. It is thus possible to simplify the fabrication process of the semiconductor device and reduce the production cost.

In the above-described first embodiment, the thickness T of the first portions 44 is different from the width W1 of the second portions 46. The first embodiment has another exemplary structure in which T is equal to W1. In view of relaxing stress applied to the bumps 40, the bumps 40 are preferably arranged in rows and columns and are spaced apart from each other at equal intervals.

FIG. 9A is a plan view of a semiconductor device seen through the upper surface of the device in accordance with a first variation of the first embodiment, and FIG. 9B is a cross-sectional view taken along a line A-A in FIG. 9A. Referring to these figures, a semiconductor device 250 employs separated solder layers as the bumps 40 provided on each of the source pad 12 and the drain pad 14. These bumps 40 may be formed by forming a solder layer on the whole surfaces of the source pad 12 and the drain pad 14 and dividing the solder layer into parts by etching or the like. Since the gate pad 16 has a comparatively small area, only one bump 40 is provided on the gate pad 16. However, a plurality of bumps 40 may be provided on the gate pad 16. The other structures of the first variations are the same as those of the semiconductor device 200 of the first embodiment, and a description thereof is omitted here.

The first variation of the first embodiment is capable of suppressing the occurrence of voids at the connection interfaces between the FET chip 10 and the pads and relaxing stress per bump 40. Thus, the first variation has a high reliability.

### Second Embodiment

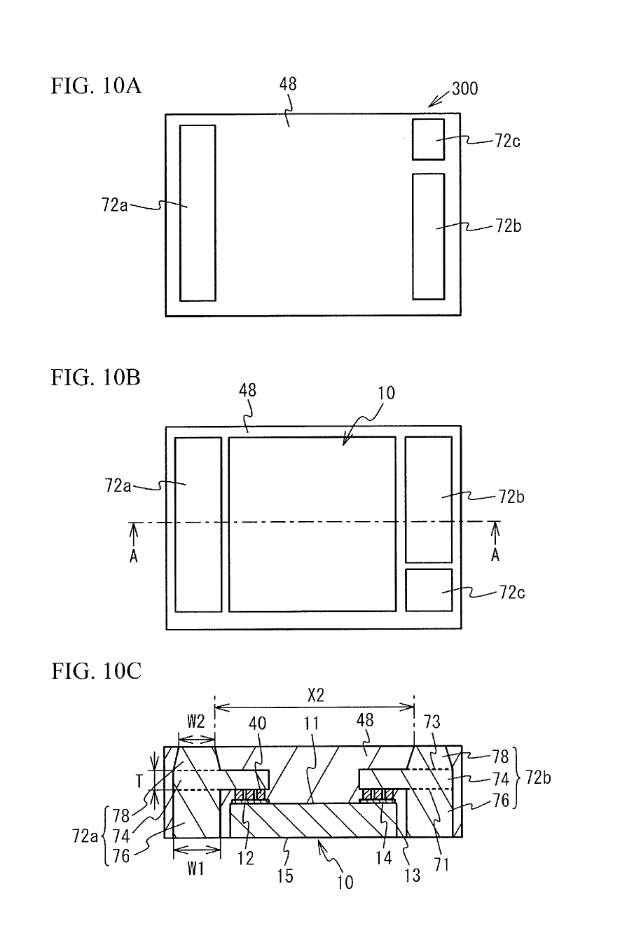

FIG. 10A is a top view of a semiconductor device in accordance with a second embodiment, FIG. 10B is a bottom view of the semiconductor device, and FIG. 10C is a cross-sectional view taken along a line A-A in FIG. 10B. Referring to these figures, a semiconductor device 300 of the second embodiment has leads 72a˜72c having shapes different from those of the leads 42a˜42c of the semiconductor device 200 of the first embodiment. Each of the leads 72a˜73c has a first portion 74, a second portion 76, and a third portion 78. The first portion 74 extends along the upper surface 11 of the FET chip 10. The second portion 76 contacts a surface 71 of the first portion 74 along the upper surface 11 of the FET chip 10 and extends along the side surface 13 of the FET chip 10. The third portion 78 contacts a surface 73 opposite to the surface 71 of the first portion 74 along the upper surface 11 of the FET chip 10, and extends in a direction away from the surface 73 (upwards). The second portion 76 and the third portion 78 are located on the opposite sides of the first portion 74. The third portion 78 has a width W2, which is different in measurement from the thickness T of the first portion 74. The width W2 of the third portion 78 is larger than the thickness T of the first portion 74. The width W1 of the second portion 76 is different from the thickness T of the first portion 74, and is larger than T, as in the case of the first embodiment. The second portion 76 and the third portion 78 are exposed from the seal layer 48. That is, the leads 72a˜72c pierce the seal layer 48. The other structures of the second embodiment are the same as those of the semiconductor device 200 of the first embodiment, and a description thereof is omitted here.

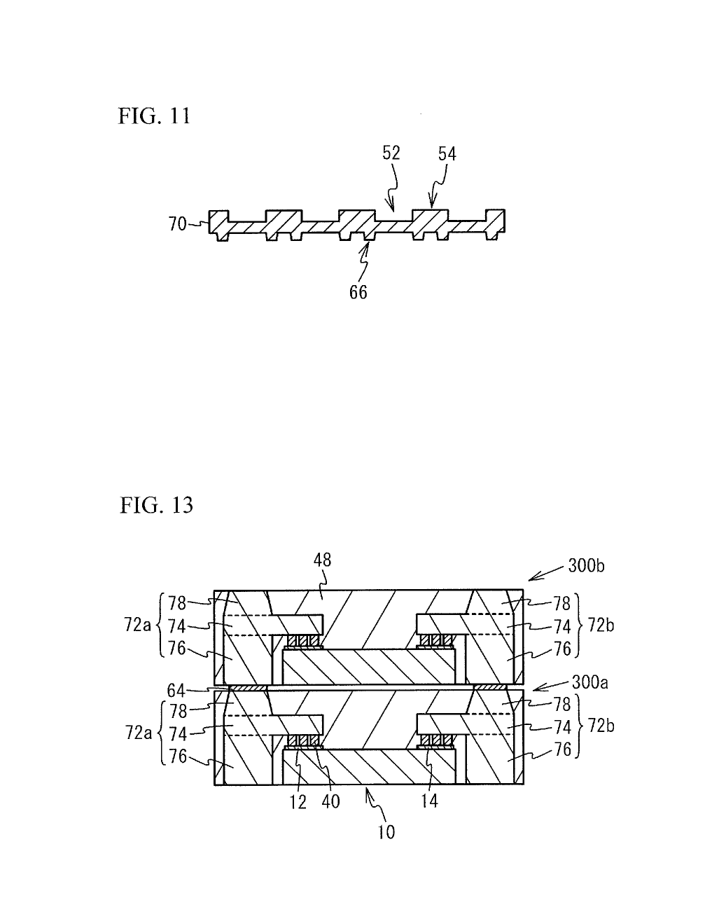

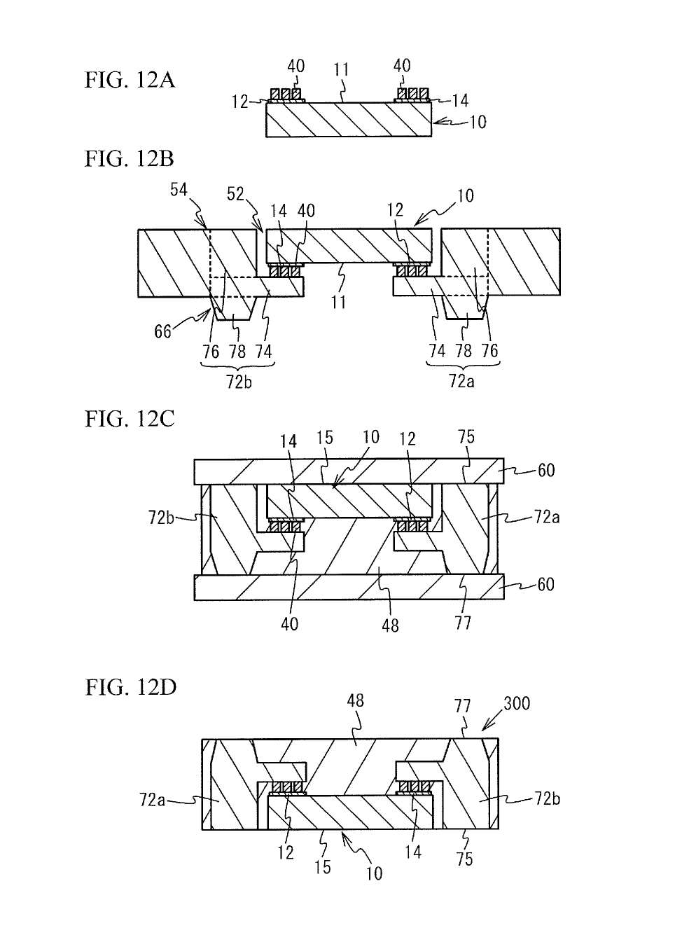

A description is given, with reference to FIGS. 11 and 12A through 12D, of a method for fabricating the semiconductor device in accordance with the second embodiment. First, a method for producing a leadframe is described with reference to FIG. 11. FIG. 11 is a cross-sectional view that illustrates a method for producing a leadframe. A metal plate 70 is prepared. The metal plate 70 has a surface in which the groove portions 52 and the bank portions 54 are arranged in turn repeatedly in the form of stripes, and an opposite surface in which protrusions 66 aligned with sides of the bank portions 54 are formed. The metal plate 70 may be formed by applying press or cutting to a flat metal plate. After that, the same steps as those previously described with reference to FIGS. 5A through 5D and 6 are carried out, whereby a leadframe divided into regions each having a plurality of leads 72a˜72c is obtained.

A description is given, with reference to FIGS. 12A through 12D, of a method for fabricating a semiconductor device with the above-described leadframe. FIGS. 12A through 12D are cross-sectional views that illustrate a method for fabricating a semiconductor device. FIGS. 12A through 12D illustrate only one semiconductor device for the sake of simplicity. As illustrated in FIG. 12A, a plurality of bumps 40 is formed on each of the source pad 12, the drain pad 14 and the gate pad 16 (not illustrated) on the upper surface 11 of the FET chip 10.

As illustrated in FIG. 12B, the bumps 40 on the pads on the upper surface 11 of the FET chip 10 are connected to the leads 72a˜72c (lead 72c is not illustrated) defined by the respective cutout patterns. More specifically, the bumps 40 are connected to the first portions 74 (that is, the groove portions 52) of the leads 72a˜72c. Thus, the FET chip 10 is arranged between the lead 72a and the lead 72b and between the lead 72a and the lead 72c so as to be surrounded by the leads 72a-72c.

As illustrated in FIG. 12C, the metal plate 70 is divided into the individual FET chips 10 by cutting. After the cutting process, the relief film 60 is attached to the lower surface 15 and surfaces 75 of the leads 72a˜72c on the lower surface 15 side of the FET chip 10 covered with the relief film 60. After that, the FET chip 10 and the leads 72a˜72c are molded. This molding forms the seal layer 48 that seals the FET chip 10 and the leads 72a˜72c.

As illustrated in FIG. 12D, the relief film 60 is removed. Thus, the lower surface 15 of the FET chip 10 and surfaces 77 of the leads 72a˜72c opposite to the surface 75 on the lower surface 15 side of the FET chip 10 are exposed from the seal layer 48. FIG. 12D illustrates the packaged semiconductor device 300 of the second embodiment.

In the semiconductor device 300 of the second embodiment, the leads 72a˜72c pierce the seal layer 48, and are exposed from the surfaces of the leads 72a˜72c on the lower surface 15 of the FET chip 10 and the opposite surfaces thereof. Thus, a plurality of semiconductor devices 300 may be stacked with electric interconnections being made. FIG. 13 is a cross-sectional view of a device having two stacked semiconductor devices of the second embodiment. Referring to FIG. 13, the third portions 78 of the leads 72a˜72c of a lower semiconductor device 300a are connected, by solders 64, to the second portions 76 of the leads 72a˜72c of an upper semiconductor device 300b. Thus, the semiconductor devices 300a and 300b are electrically interconnected and are vertically stacked. This stacking is not limited to two but three semiconductor devices or more may be stacked similarly.

According to the second embodiment, as illustrated in FIG. 10C, each of the leads 72a˜72c includes the first portion 74, the second portion 76 and the third portion 78. The first portion 74 is connected to the bumps 40 provided on the pads on the upper surface 11 of the FET chip 10, and extends along the upper surface of the FET chip 10. The second portion 76 contacts a surface 71 of the first portion 74 along the upper surface 11 of the FET chip 10 and extends along the side surface 13 of the FET chip 10. The third portion 78 contacts a surface 73 opposite to the surface 71 of the first portion 74 along the upper surface 11 of the FET chip 10, and extends in the direction away from the surface 73. With the above structure, the leads 72a˜72c pierce the seal layer 48, and are exposed from the surface on the lower surface 15 side of the FET chip 10 and its opposite surface. Therefore, as illustrated in FIG. 13, the stacked semiconductor device is obtained in which the third portions 78 of the leads 72a˜72c of the lower semiconductor device 300a are connected to the second portions 76 of the leads 72a˜72c of the upper semiconductor device 300b. Since the leads 72a˜72c pierce the seal layer 48 and are exposed, the assembly of the stacked semiconductor devices has a reduced ON resistance. As a result, heat radiation of the semiconductor devices is suppressed and the reliability of the semiconductor devices is improved.

As illustrated in FIG. 10C, it is preferable that the third portion 78 of each of the leads 72a˜72c faces the second portion 76 through the first portion 74, and extends on an imaginary extension line of the second portion 76. It is thus possible to enlarge the distance X2 between the third portion 78 of the lead 72a and the third portion 78 of the lead 72b and to improve the reliability of the semiconductor device.

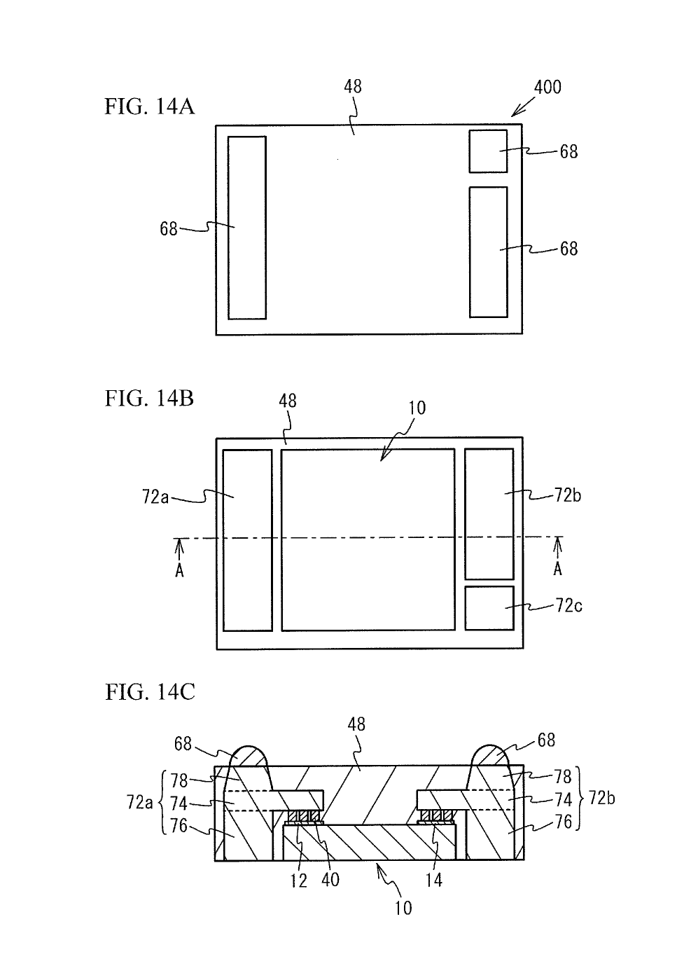

FIG. 14A is a top view of a semiconductor device in accordance with a first variation of the second embodiment, FIG. 14B is a bottom view of the present semiconductor device, and FIG. 14C is a cross-sectional view taken along a line A-A in FIG. 14B. Referring to these figures, a semiconductor device 400 of the first variation of the second embodiment has protrusion electrodes 68, which protrude from the seal layer 48 and are provided on the third portions of the leads 72a˜72c. The protrusion electrode 68 on the left side of FIG. 14A is provided on the third portion 78 of the lead 72a, the protrusion electrodes 68 on the lower right side are provided on the third portion 78 of the lead 72b, and the protrusion electrode 68 on the upper right side is provided on the third portion 78 of the lead 72c. The other structures of the present semiconductor device are the same as those of the semiconductor device 300 of the second embodiment, and a description thereof is omitted here.

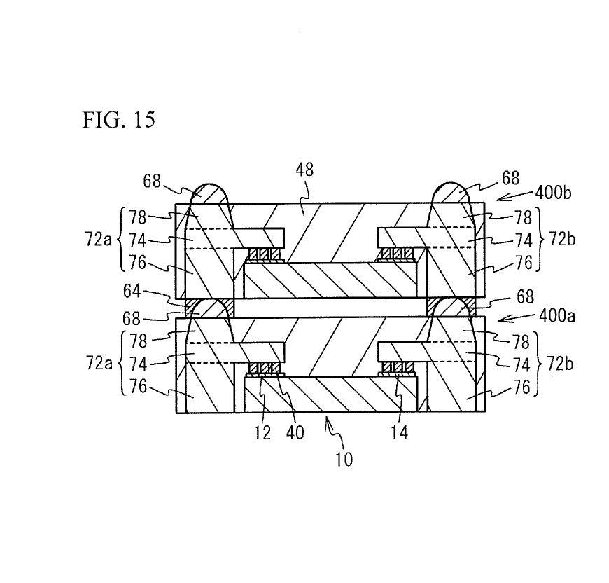

FIG. 15 is a cross-sectional view of a semiconductor device in which two semiconductor devices of the first variation of the second embodiment are stacked. As illustrated in FIG. 15, the protrusion electrodes 68 provided on the third portions 78 of the leads 72a˜72c of the lower semiconductor device 400a are connected, by solders 64, to the second portions 76 of the leads 72a˜72c of the upper semiconductor device 400b. The protrusion electrodes 68 make a spacing between the semiconductor devices 400a and 400b larger than the spacing between the semiconductor devices 300a and 300b illustrated in FIG. 13. The above stacking is not limited to two but three semiconductor devices or more may be stacked similarly.

According to the first variation of the second embodiment, as illustrated in FIG. 14C, the protrusion electrodes 68 are provided on the third portions 78 of the leads 72a˜72c. The protrusion electrodes 68 realize an enlarged spacing between the semiconductor devices 400a and 400b in FIG. 15, as compared to the spacing between the semiconductor devices 300a and 300b in FIG. 13. A larger amount of solders 64 may be used for bonding the semiconductor devices 400a and 400b, and the self-alignment effect is more effectively produced. Thus, the semiconductor devices 400a and 400b may be more easily aligned with each other.

From a viewpoint of downsizing the assembly of the stacked semiconductor devices while the easy alignment effect of the semiconductor devices to be stacked is produced, the height of the protrusion electrodes 68 is preferably equal to or larger than 150 μm, more preferably equal to or larger than 175 μm, and is much more preferably equal to or larger than 200 μm. In order to produce the self-alignment effect, the height of the protrusion electrodes 68 is equal to or smaller than 300 μm, more preferably equal to or smaller than 250 μm, and is much more preferably equal to or smaller than 200 μm.

The protrusion electrodes 68 may be integrally formed with the leads 72a˜72c when the leads 72a˜72c are produced. Another method uses solders deposited on the third portions 78 of the leads 72a˜72c. In this case, for example, solder printing may be used to form the solder protrusion electrodes 68 since the third portions 78 of the leads 72a˜72c are exposed from the seal layer 48 so as to have the rectangular shapes.

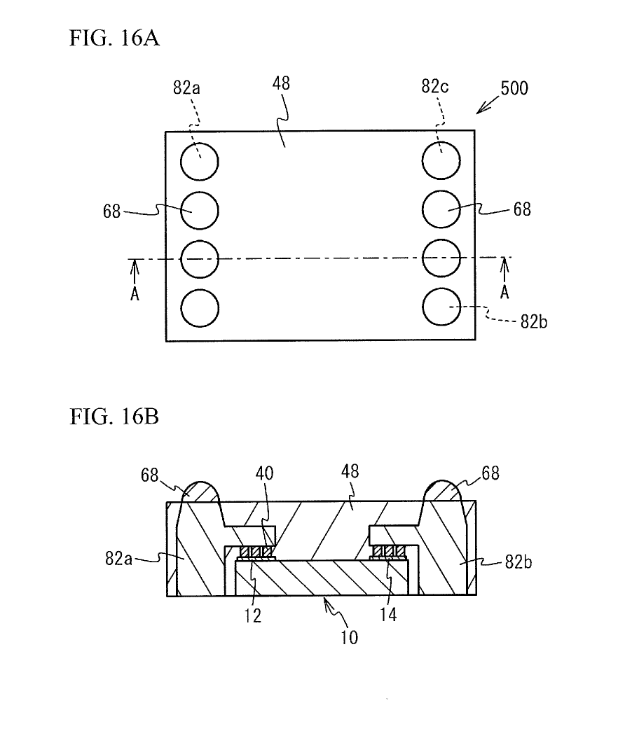

FIG. 16A is a top view of a semiconductor device in accordance with a second variation of the second embodiment, and FIG. 16B is a cross-sectional view taken along a line A-A in FIG. 16A. As illustrated in FIGS. 16A and 16B, a semiconductor device 500 of the second variation of the second embodiment has leads 82a˜82c having circular portions exposed from the seal layer 48, and the protrusion electrodes 68 are provided on the exposed circular portions. Four protrusion electrodes 68 on the left side of FIG. 16A are provided on the lead 82a, and three protrusion electrodes 68 the lower right side of FIG. 16A are provided on the lead 82b, and one protrusion electrode 68 on the upper right side is provided on the lead 82c. The other structures of the second variation are the same as those of the semiconductor device 400 of the first variation of the second embodiment, and a description thereof is omitted here.

According to the second variation of the second embodiment, the leads 82a˜82c are exposed in the form of a circle, and the protrusion electrodes 68 are provided on the exposed circular portions of the leads 82a˜82c. If the protrusion electrodes 68 are formed of solder, solder balls are mounted on the circular portions of the leads 82a˜82c exposed from the seal layer 48. It is thus possible to easily form the protrusion electrodes in the predetermined positions.

In the first and second embodiments, the plurality of bumps 40 are provided on each of the source pad 12, the drain pad 14 and the gate pad 16. However, the present invention is not limited to the above. For example, at least two bumps 40 are provided on at least one of the pads while taking the bump size into consideration. For example, if the semiconductor device has the source pad, the drain pad and the gate pad, a plurality of bumps are preferably provided on at least one of the source pad or the drain pad.

The FET chip 10 is not limited to the HEMT using the GaN-based semiconductor but may be another type of FET chip. For example, the FET chip 10 is a HEMT using a GaAs-based semiconductor (a semiconductor including GaAs), or a FET chip other than HEMT such as MESFET and MOSFET. It is to be noted that the HEMT chip using the GaN-based semiconductor is capable of operating at high voltages and is required to have a high breakdown voltage. Therefore, large effects are produced especially when the FET chip 10 is a HEMT chip using the GaN-based semiconductor. The bumps 40 are not limited to the solder bumps but may be bumps made of another material such as Au bumps and Cu bumps.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A semiconductor device comprising:
a field effect transistor (FET) chip;
pads provided on an upper surface of the FET chip;
bumps provided on at least one of the pads;
leads that include first portions that are connected to the FET chip by the bumps and extend along the upper surface of the FET chip, and second portions that contact surfaces of the first portions along the upper surface of the FET chip and extend along a side surface of the FET chip, the leads being formed by press or cutting; and
a seal layer that seals the FET chip and the leads and a surface from which the second portions of the leads are exposed, the surface of the seal layer being on a lower surface side of the FET chip.

2. The semiconductor device according to claim 1, wherein the first portions of the leads have a thickness different in measurement from a width of the second portions.

3. The semiconductor device according to claim 1, wherein the second portion of one of the leads connected to a source pad that is one of the pads and the second portion of another one of the leads connected to a drain pad that is another one of the pads are exposed from the seal layer in positions between which the FET chip is interposed.

4. The semiconductor device according to claim 1, wherein the FET chip is a high electron mobility transistor chip.

5. The semiconductor device according to claim 1, wherein the FET chip is a high electron mobility transistor chip using a GaN-based semiconductor.

6. The semiconductor device according to claim 1, wherein the bumps provided on the at least one of the pads are arranged in rows and columns at equal intervals.

7. The semiconductor device according to claim 1, wherein the leads have third portions that contact opposite surfaces of the first portions to the surfaces of the first portions along the upper surface of the FET chip and extend a direction away from the opposite surfaces, and the third portions are exposed from the seal layer.

8. The semiconductor device according to claim 7, wherein the third portions contact surfaces of the first portions opposite to the surfaces of the first portions along the upper surface of the FET chip, and extends on an imaginary extension line of the second portion.

9. The semiconductor device according to claim 7, wherein the third portions have a width different in measurement from a thickness of the first portions.

10. The semiconductor device according to claim 7, further comprising protrusion electrodes provided on the third portions of the leads exposed from the seal layer.

11. The semiconductor device according to claim 10, wherein the protrusion electrodes have a height equal to or larger than 150 μm.

12. The semiconductor device according to claim 7, wherein the third portions of the leads exposed from the seal layer have a rectangular shape.

13. The semiconductor device according to claim 7, wherein the third portions of the leads exposed from the seal layer have a circular shape.

14. A semiconductor device comprising first and second semiconductor devices each including:
a field effect transistor (FET) chip;
pads provided on an upper surface of the FET chip;
bumps provided on at least one of the pads;
leads that include first portions that are connected to the FET chip by the bumps and extend along the upper surface of the FET chip, and second portions that contact surfaces of the first portions along the upper surface of the FET chip and extend along a side surface of the FET chip; and
a seal layer that seals the FET chip and the leads and a surface from which the second portions of the leads are exposed, the surface of the seal layer being on a lower surface side of the FET chip,
the leads that include third portions that contact opposite surfaces of the first portions to the surfaces of the first portions along the upper surface of the FET chip and extend a direction away from the opposite surfaces, the third portions being exposed from the seal layer,
the first and second semiconductor devices that include a stacked structure in which the third portions of the leads of the first semiconductor device are connected to the second portions of the leads of the second semiconductor device.

15. A method for fabricating a semiconductor device comprising:
preparing a metal plate that includes groove portions and bank portions arranged in a form of stripes;
forming cutout patterns that define leads extending from the groove portions to the bank portions in the metal plate by press or cutting;
connecting bumps provided on pads on an upper surface of each of field effect transistor (FET) chips to the groove portions of the leads defined by the cutout patterns, at least two bumps out of the bumps being provided on at least one of the pads,
dividing the metal plate into individual FET chips by cutting; and
forming a seal layer that seals the individual FET chips and the leads so that surfaces of the leads along lower surfaces of the individual FET chips are exposed.

16. The method according to claim 15, wherein:
the forming of the cutout patterns forms the cutout patterns arranged in rows and columns in the metal plate; and
the connecting of the bumps connects the bumps provided on the pads on the upper surfaces of the FET chips to the groove portions of the leads defined by the cutout patterns.

17. The method according to claim 15, wherein the preparing of the metal plate prepares the metal plate that includes protrusions that are provided on a surface of the metal plate opposite to another surface on which the groove portions and the bank portions are arranged and are aligned with sides of the bank portions.
